(19) United States
(12) Patent Application Publication
(10) Pub. No.: US 2024/0297270 A1
(43) Pub. Date: Sep. 5, 2024

(54) Green LED With Current-Invariant Emission Wavelength

(71) Applicant: Lumileds LLC, San Jose, CA (US)

(72) Inventor: Robert Armitage, Cupertino, CA (US)

(73) Assignee: Lumileds LLC, San Jose, CA (US)

(21) Appl. No.: 18/280,974

(22) PCT Filed: Mar. 16, 2022
(86) PCT No.: PCT/US2022/020485

§ 371 Date: Sep. 8, 2023

Related U.S. Application Data
(60) Provisional application No. 63/164,155, filed on Mar. 22, 2021.

(51) Int. Cl. H01L 33/32; H01L 33/06

(52) U.S. Cl. CPC H01L 33/325; H01L 33/06

(57) ABSTRACT

Described are light emitting diode (LED) devices including a quantum well on a superlattice structure. The LED device has a dominant wavelength greater than 520 nm. The dominant wavelength changes less than 7 nm when the current density increases from 10 A/cm² to 100 A/cm² and a junction temperature of the device changes less than 20° C.

### GOVERNMENT LICENSE RIGHTS

This invention was made with U.S. Government support under Award No. DE-EE009163 awarded by Department of Energy (DOE). The U.S. Government has certain rights in the invention.

### TECHNICAL FIELD

Embodiments of the disclosure generally relate to arrays of light emitting diode (LED) devices and methods of manufacturing the same. More particularly, embodiments are directed to light emitting diode devices, specifically green LED, with an emission wavelength that is nearly invariant with respect to changes in operating current density over more than 2 orders of magnitude.

### BACKGROUND

A light emitting diode (LED) is a semiconductor light source that emits visible light when current flows through it. LEDs combine a P-type semiconductor with an N-type semiconductor. LEDs commonly use a III-group compound semiconductor. A III-group compound semiconductor provides stable operation at a higher temperature than devices that use other semiconductors. The III-group compound is typically formed on a substrate formed of sapphire or silicon carbide (SiC).

An illumination system with tunable color temperature and luminance can be fabricated by mixing the emission of three or more direct color LEDs. The color temperature may be tuned from cool white to warm white by increasing the relative intensity emitted by the longer wavelength LEDs and/or decreasing the relative intensity emitted by shorter wavelength LEDs. Control of the color temperature and luminance requires operating each of the LEDs over a range of different currents, especially for applications in compact and low-cost illumination systems that use a minimal number of LEDs. The color coordinates of blue, amber, and red LEDs tend to be quite stable with respect to changes in operating current, but that is not the case for green LEDs. The emission of state-of-the-art green LEDs invariably shifts to shorter wavelength when the operating current increases. An LED which emits green at low current density can appear cyan or even blue at higher current density. The current-dependent shift in color of green LEDs is a complication and limitation in the design of practical illumination systems based on color mixing, making it challenging to obtain the desired color temperature and color rendering index for multiple luminance levels. Accordingly, there is a need for improved LED devices.

### SUMMARY

Embodiments of the disclosure are directed to LED devices and methods for manufacturing LED devices. In one or more embodiments, a light emitting diode (LED) device comprises: a quantum well, the device having a dominant wavelength greater than 520 nm, the dominant wavelength changing less than 7 nm when the current density increases from 10 A/cm² to 100 A/cm² and a junction temperature of the device changes less than 20° C.

Other embodiments of the disclosure are directed to a light emitting diode (LED) system comprising: a light emitting diode (LED) array comprising: a nucleation layer on a substrate; an n-type layer on the nucleation layer; a quantum well on the n-type layer, the quantum well comprising an indium gallium nitride (InGaN) well and a gallium nitride (GaN) barrier layer; a plurality of p-type layers on the quantum well; and a p-type contact layer on the plurality of p-type layers. The device has a dominant wavelength greater than 520 nm, the dominant wavelength changing less than 7 nm when the current density increases from 10 A/cm² to 100 A/cm² a junction temperature of the device changes less than 20° C.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments. The embodiments as described herein are illustrated by way of example and not limitation in the figures of the accompanying drawings in which like references indicate similar elements.

FIG. 1 illustrates a cross-sectional view of an LED device;

FIG. 2 is a graph showing the current density of an LED device versus the dominant wavelength at 25° C.;

FIG. 3 is a graph showing the current density of an LED device versus the dominant wavelength at 85° C.; and

FIG. 4 is a graph showing the absolute value of the wavelength decrease with an increase in current density from 10-50 A/cm² for an LED device.

To facilitate understanding, identical reference numerals have been used, where possible, to designate identical elements that are common to the figures. The figures are not drawn to scale. For example, the heights and widths of the mesas are not drawn to scale.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “substrate” as used herein according to one or more embodiments refers to a structure, intermediate or final, having a surface, or portion of a surface, upon which a process acts. In addition, reference to a substrate in some embodiments also refers to only a portion of the substrate, unless the context clearly indicates otherwise. Further, reference to depositing on a substrate according to some embodiments includes depositing on a bare substrate or on a substrate with one or more layers, films, features or materials deposited or formed thereon.

In one or more embodiments, the “substrate” means any substrate or material surface formed on a substrate upon which film processing is performed during a fabrication process. In exemplary embodiments, a substrate surface on which processing is performed includes materials such as silicon, silicon oxide, silicon on insulator (SOI), strained silicon, amorphous silicon, doped silicon, carbon doped silicon oxides, germanium, gallium arsenide, glass, sapphire, and any other suitable materials such as metals, metal nitrides, III-nitrides (e.g., GaN, AlN, InN, and other alloys), metal alloys, and other conductive materials, depending on the application. Substrates include, without limitation, light emitting diode (LED) devices. Substrates in some embodiments are exposed to a pretreatment process to polish, etch, reduce, oxidize, hydroxylate, anneal, UV cure, e-beam cure and/or bake the substrate surface. In addition to film processing directly on the surface of the substrate itself, in some embodiments, any of the film processing steps disclosed is also performed on an underlayer formed on the substrate, and the term “substrate surface” is intended to include such underlayer as the context indicates. Thus for example, where a film/layer or partial film/layer has been deposited onto a substrate surface, the exposed surface of the newly deposited film/layer becomes the substrate surface.

The term “wafer” and “substrate” will be used interchangeably in the instant disclosure. Thus, as used herein, a wafer serves as the substrate for the formation of the LED devices described herein.

Embodiments described herein describe LED devices and methods for forming LED devices. In particular, the present disclosure describes LED devices and methods to produce LED devices which advantageously emit green light with a color that is substantially invariant over more than two orders of magnitude change in current density. In one or more embodiments, the epitaxy design makes it possible to obtain the desired color temperature and color rendering index for multiple luminance levels. The LED of one or more embodiments could also be useful for microLED (uLED) applications. For example, since the color is independent of current density, the color point can remain stable at both low brightness and high brightness display settings within a device, and the same epitaxial wafers could be used to make lower-brightness emitters for phone and TV displays as well as higher-brightness emitters for augmented and virtual reality applications.

In the absence of an external bias, internal electric fields naturally exist across InGaN quantum wells (QWs) grown in the conventional c-plane crystal orientation. These fields originate from polarization charges at interfaces between InGaN wells and the barrier layers (typically GaN). The polarization charges and corresponding electric fields are larger for green QWs than blue QWs due to the higher indium concentrations needed for green emission. Through the quantum-confined Stark effect, the internal electric fields have a strong influence on the emission wavelength of green QWs. The internal electric fields may be modified by application of an external bias (such as a forward bias applied to operate the LED) or by the injection of high densities of charge carriers (as occurs when an LED is operated at high current). Due to these factors, the wavelengths of state-of-the-art green LEDs are unstable with respect to changes in operating current. Moreover, for a given epitaxy design the wavelength instability gets worse when the QW indium concentration is increased to extend the wavelength longer into the green spectral range.

For a conventional LED with an n-type layer grown before the active region and p-type layer, a forward bias applied to the LED increases the magnitude of the internal electric field and causes the emission to shift to longer wavelength. On the other hand, a high current density passing through the QWs causes the emission to shift to shorter wavelength due to the screening effect. In one or more embodiments, it is possible to almost exactly compensate the wavelength decrease due to electric field screening with the wavelength increase due to electric field increase with applied forward bias.

In one or more embodiments, provided is an LED having a dominant wavelength of greater than 520 nm which changes less than 7 nm as the current density increases from 10 A/cm² to 100 A/cm² at a fixed junction temperature. In some embodiments, the dominant wavelength changes less than 3 nm as the current density increases from 35 A/cm² to 100 A/cm² at fixed junction temperature. In further embodiments, the dominant wavelength changes less 2 nm as the current density increases from 35 to 100 A/cm² at a fixed junction temperature. In some embodiments, the LED has an external quantum efficiency (EQE) greater than 20% when operated at 35 A/cm² at room temperature.

In one or more embodiments, the LED is built from gallium-nitride based epitaxy grown in the c-plane orientation, manufacturable with MOCVD equipment and using a conventional substrate material such as sapphire, silicon, or SiC. In one or more embodiments, the LED comprises a quantum well. In some embodiments, the quantum well is on a superlattice structure. In some embodiments, the quantum well is a multiple quantum well.

The embodiments of the disclosure are described by way of the Figures, which illustrate devices and processes for forming devices in accordance with one or more embodiments of the disclosure. The processes shown are merely illustrative possible uses for the disclosed processes, and the skilled artisan will recognize that the disclosed processes are not limited to the illustrated applications.

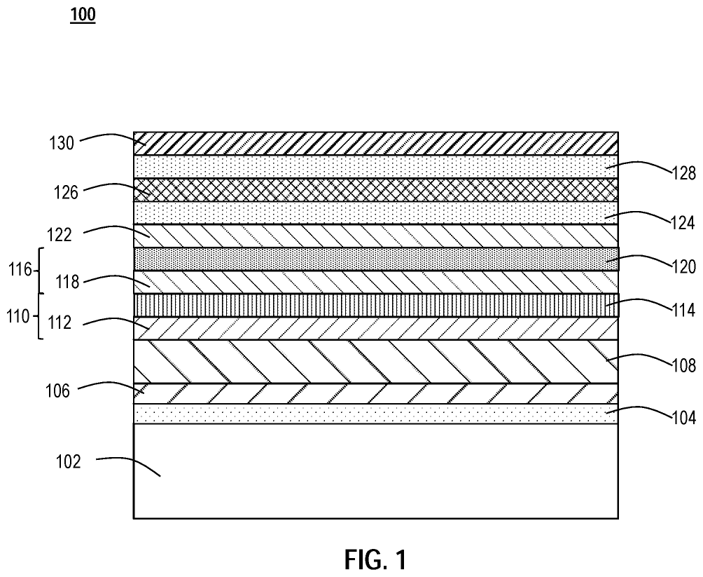

One or more embodiments of the disclosure are described with reference to the Figures. FIG. 1 illustrates a cross-sectional view of a device 100 according to one or more embodiments. An aspect of the disclosure pertains to a method of manufacturing a LED array. Referring to FIG. 1, a LED device 100 is manufactured having a dominant wavelength of greater than 520 nm which changes less than 7 nm as the current density increases from 10 A/cm² to 100 A/cm² at a fixed junction temperature.

In one or more embodiments, a nucleation layer 104 and a defect reduction layer 106 are grown on a substrate 102, followed by an n-type layer 108. In some embodiments, a superlattice 110 comprised of alternating pairs of an indium gallium nitride (InGaN) layer 112 and a gallium nitride (GaN) layer 114 is grown over the n-type layer 108. In one or more embodiments, the superlattice 110 comprises a range of from 5 to 70 alternating pairs of an InGaN layer 112 and a GaN layer 114, or a range of from 10 to 50 alternating pairs of an InGaN layer 112 and a GaN layer 114. In one or more embodiments, the superlattice 110 has a periodicity of 5 nm. The superlattice 110 may be doped with silicon (Si) in the range 1-6×10¹⁸ cm⁻³ and the indium concentration is <10% . In some embodiments, the superlattice 110 is not present.

The substrate 102 may be any substrate known to one of skill in the art which is configured for use in the formation of LED devices. In one or more embodiments, the substrate 102 comprises one or more of sapphire, silicon carbide, silica (Si), quartz, magnesium oxide (MgO), zinc oxide (ZnO), spinel, and the like. In one or more embodiments, the substrate 102 is a transparent substrate. In specific embodiments, the substrate 102 comprises sapphire. In one or more embodiments, the substrate 102 is not patterned prior to formation of the LEDs. Thus, in some embodiments, the substrate is 102 not patterned and can be considered to be flat or substantially flat. In other embodiments, the substrate 102 is a patterned substrate.

In one or more embodiments, the n-type layer 108 may comprise any Group III-V semiconductors, including binary, ternary, and quaternary alloys of gallium (Ga), aluminum (Al), indium (In), and nitrogen (N), also referred to as III-nitride materials. Thus, in some embodiments, the n-type layer 108 comprises one or more of gallium nitride (GaN), aluminum nitride (AlN), indium nitride (InN), gallium aluminum nitride (GaAlN), gallium indium nitride (GaInN), aluminum gallium nitride (AlGaN), aluminum indium nitride (AlInN), indium gallium nitride (InGaN), indium aluminum nitride (InAlN), and the like. In a specific embodiment, the n-type layer 108 comprises gallium nitride (GaN). In one or more embodiments, the n-type layer 108 is doped with n-type dopants, such as silicon (Si) or germanium (Ge). The n-type layer 108 may have a dopant concentration significant enough to carry an electric current laterally through the layer. In some embodiments, the n-type layer 108 comprises a GaN current spreading layer.

In one or more embodiments, a nucleation layer 104 is formed on the substrate 102 prior to the defect reduction layer 106. In one or more embodiments, the nucleation layer comprises 104 a III-nitride material. In specific embodiments, the nucleation layer 104 comprises gallium nitride (GaN) or aluminum nitride (AlN).

In one or more embodiments, the layers of III-nitride material may be deposited by one or more of sputter deposition, atomic layer deposition (ALD), metalorganic chemical vapor deposition (MOCVD), physical vapor deposition (PVD), plasma enhanced atomic layer deposition (PEALD), and plasma enhanced chemical vapor deposition (PECVD).

“Sputter deposition” as used herein refers to a physical vapor deposition (PVD) method of thin film deposition by sputtering. In sputter deposition, a material, e.g. a III-nitride, is ejected from a target that is a source onto a substrate. The technique is based on ion bombardment of a source material, the target. Ion bombardment results in a vapor due to a purely physical process, i.e., the sputtering of the target material.

As used according to some embodiments herein, “atomic layer deposition” (ALD) or “cyclical deposition” refers to a vapor phase technique used to deposit thin films on a substrate surface. The process of ALD involves the surface of a substrate, or a portion of substrate, being exposed to alternating precursors, i.e. two or more reactive compounds, to deposit a layer of material on the substrate surface. When the substrate is exposed to the alternating precursors, the precursors are introduced sequentially or simultaneously. The precursors are introduced into a reaction zone of a processing chamber, and the substrate, or portion of the substrate, is exposed separately to the precursors.

As used herein according to some embodiments, “chemical vapor deposition” refers to a process in which films of materials are deposited from the vapor phase by decomposition of chemicals on a substrate surface. In CVD, a substrate surface is exposed to precursors and/or co-reagents simultaneous or substantially simultaneously. A particular subset of CVD processes commonly used in LED manufacturing use metalorganic precursor chemical and are referred to as MOCVD or metalorganic vapor phase epitaxy (MOVPE). As used herein, “substantially simultaneously” refers to either co-flow or where there is overlap for a majority of exposures of the precursors.

As used herein according to some embodiments, “plasma enhanced atomic layer deposition (PEALD)” refers to a technique for depositing thin films on a substrate. In some examples of PEALD processes relative to thermal ALD processes, a material may be formed from the same chemical precursors, but at a higher deposition rate and a lower temperature. In a PEALD process, in general, a reactant gas and a reactant plasma are sequentially introduced into a process chamber having a substrate in the chamber. The first reactant gas is pulsed in the process chamber and is adsorbed onto the substrate surface. Thereafter, the reactant plasma is pulsed into the process chamber and reacts with the first reactant gas to form a deposition material, e.g. a thin film on a substrate. Similarly to a thermal ALD process, a purge step may be conducted between the deliveries of each of the reactants.

As used herein according to one or more embodiments, “plasma enhanced chemical vapor deposition (PECVD)” refers to a technique for depositing thin films on a substrate. In a PECVD process, a source material, which is in gas or liquid phase, such as a gas-phase III-nitride material or a vapor of a liquid-phase III-nitride material that have been entrained in a carrier gas, is introduced into a PECVD chamber. A plasma-initiated gas is also introduced into the chamber. The creation of plasma in the chamber creates excited radicals. The excited radicals are chemically bound to the surface of a substrate positioned in the chamber, forming the desired film thereon.

In one or more embodiments, LED device 100 is manufactured by placing the substrate 102 in a metalorganic vapor-phase epitaxy (MOVPE) reactor so that the LED device layers are grown epitaxially.

In one or more embodiments, a quantum well 116 is formed on the superlattice 110. The quantum well 116 comprises pairs of a quantum barrier layer 118 and a green quantum well 120. The quantum barrier layer 118 may comprise any suitable material known to the skilled artisan. In some embodiments, the quantum barrier layer 118 comprises a gallium nitride (GaN) layer. The green quantum well 120 may comprise any suitable material known to the skilled artisan. In some embodiments, the green quantum well 120 comprises indium gallium nitride (InGaN) wells. The quantum well 116 may comprise different layers of indium gallium nitride (InGaN) and gallium nitride (GaN). The emission color may be controlled by the relative mole fractions of indium (In) and gallium (Ga) in the InGaN layer and/or by the thicknesses of the quantum wells/multiple quantum wells.

The quantum well 116 may be formed using any deposition technique known to one of skill in the art. The quantum well 116 may comprise a sequence of quantum wells emitting the same wavelength of light. In one or more embodiments, the quantum well 116 emits light having a wavelength in a range of from greater than 520 nm to 575 nm.

In one or more embodiments, an individual quantum well within the quantum well 116 may have an InGaN thickness in a range of from about 0.5 nm to about 10 nm and a GaN barrier thickness in a range of from about 2 nm to about 100 nm. The total number of quantum wells in the quantum well 116 may be in a range of from 1 to 30.

In one or more embodiments, the active region has a green wavelength which is nearly invariant with large changes in forward bias and current density. Furthermore, a similarly stable wavelength characteristic is measured for the epitaxy design for both high and low QW indium concentrations within the green-emitting range. In other words, the stable wavelength characteristic is a feature of the overall active region design and is not specific to a particular QW indium concentration.

In some embodiments, the quantum well 116 is an eight to sixteen period quantum well. In some embodiments, the quantum well 116 is an eleven period quantum well. In one or more embodiments, the quantum well 116 has a periodicity of 19 nm. The indium concentration of the green quantum well 120 may be greater than 14% mole fraction. In some embodiments, the indium concentration of the green quantum well 120 is in a range of from greater than 14% mole fraction to less than or equal to 30% mole fraction. In one or more embodiments, the quantum well 116 comprises an active region. In some embodiments, the active region is doped with silicon (Si) having an average concentration in a range of from 1×10¹⁷ cm⁻³ to 5×10¹⁷ cm⁻³. In other embodiments, the active region is doped with silicon (Si) having an average concentration in a range of from 2×10¹⁷ cm⁻³ to 3×10¹⁷ cm⁻³.

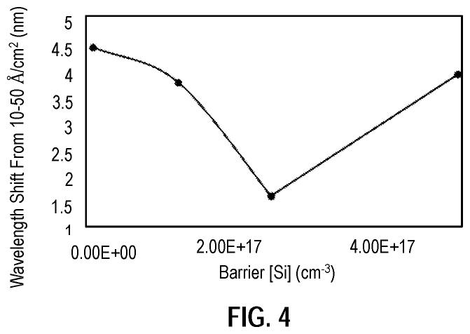

In one or more embodiments, the barrier silicon (Si) doping concentration is a crucial parameter to minimize wavelength differences with changes in operating voltage and current density. Si doping in the barriers can have a desirable effect on the voltage drop across the barriers and carrier screening in the QWs. Experimentally, an average Si concentration of about 2.5×10¹⁷ cm⁻³ has been found to be optimal. FIG. 4 is a graph showing the absolute value of the wavelength decrease with an increase in current density from 10-50 A/cm² for an LED device. A barrier Si doping concentration that is either too low or too high results in a less stable wavelength characteristic, as illustrated in FIG. 4.

In one or more embodiments, a plurality of p-type layers 124, 126, 128 are grown over the quantum well 116. In one or more embodiments, the plurality of p-type layers 124, 126, 128 may comprise any Group III-V semiconductors, including binary, ternary, and quaternary alloys of gallium (Ga), aluminum (Al), indium (In), and nitrogen (N), also referred to as III-nitride materials. Thus, in some embodiments, the plurality of p-type layers 124, 126, 128 comprises one or more of gallium nitride (GaN), aluminum nitride (AlN), indium nitride (InN), gallium aluminum nitride (GaAlN), gallium indium nitride (GaInN), aluminum gallium nitride (AlGaN), aluminum indium nitride (AlInN), indium gallium nitride (InGaN), indium aluminum nitride (InAlN), and the like.

In some embodiments, the plurality of p-type layers 124, 126, 128 comprise a sequence of doped p-type layers. In one or more embodiments, the plurality of p-type layers 124, 126, 128 comprises one or more of an aluminum gallium nitride (AlGaN) layer and a gallium nitride (GaN) layer. The plurality of p-type layers 124, 126, and 128 may be doped with any suitable p-type dopant known to the skilled artisan. In one or more embodiments, the plurality of p-type layers 124, 126, and 128 may be doped with magnesium (Mg). In one or more embodiments, the plurality of p-type layers 124, 126, and 128 comprise a first magnesium doped p-type aluminum gallium nitride layer, a magnesium doped p-type gallium nitride layer, and a second magnesium doped p-type aluminum gallium nitride layer. In some embodiments, an undoped p-type layer 122 is grown on the quantum well 116 prior to growth of the plurality of p-type layers 124, 126, 128. In one or more embodiments, the AlGaN composition is in a range of from 10% to 30% mole fraction aluminum (Al).

In one or more embodiments, a p-type contact layer 130 is grown over the plurality of p-type layers 124, 126, 128. In one or more embodiments, the p-type contact layer 130 may comprise any suitable material known to the skilled artisan. In one or more embodiments, the p-type contact layer 130 comprises a p-contact material selected from one or more of aluminum (Al), silver (Ag), gold (Au), platinum (Pt), and palladium (Pd). In specific embodiments, the p-type contact layer 130 comprises silver (Ag). In some embodiments, additional metals may be added in small quantities to the p-type contact layer 130 as adhesion promoters. Such adhesion promoters, include, but are not limited to, one or more of nickel (Ni), titanium (Ti), and chromium (Cr).

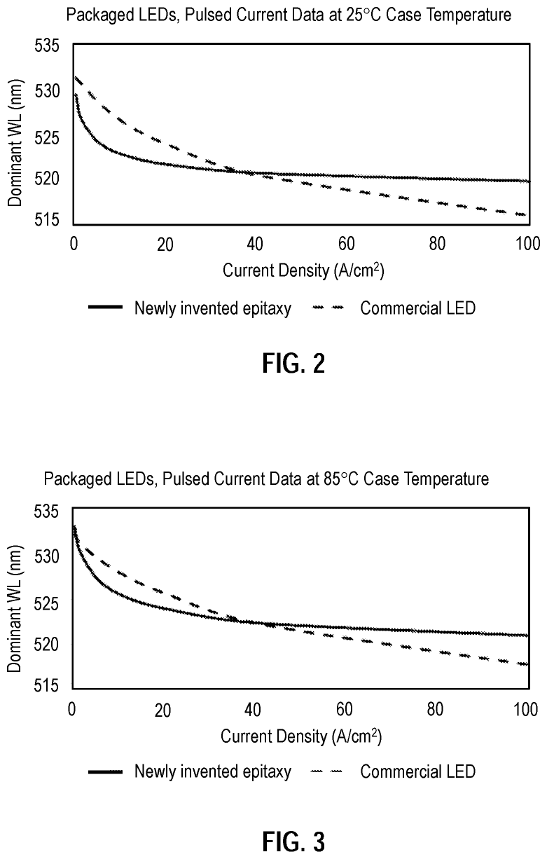

FIG. 2 is a graph showing the current density of an LED device versus the dominant wavelength at 25° C. FIG. 3 is a graph showing the current density of an LED device versus the dominant wavelength at 85° C. The measurements were conducted under pulsed driving current of 20 millisecond pulses, 2% duty cycle. There was negligible heating of devices with increasing current density for above measurement conditions. In some embodiments, the device temperature can be changed independent of current density with an external heater. As illustrated in FIGS. 2 and 3, the wavelength increases slightly at a given current density when the case temperature is increased to 85° C. instead of 25° C. Improved wavelength stability is shown regardless of the device operating temperature.

In one or more embodiments, the LED device 100 comprising the quantum well 116 on the superlattice structure 110 has a dominant wavelength greater than 520 nm. In some embodiments, the dominant wavelength changes less than 7 nm when the current density increases from 10 A/cm² to 100 A/cm² and a junction temperature of the device changes less than 20° C. In other embodiments, the dominant wavelength changes less than 3 nm as the current density increases from 35 A/cm² to 100 A/cm². In some embodiments, the device 100 may have an external quantum efficiency (EQE) greater than 20% when operated at 35 A/cm² at room temperature.

Advantageously, the change in wavelength with respect to the change in current density for the LED device of one or more embodiments is much reduced compared to state-of-the-art green LEDs. The LED device of one or more embodiments facilitates design of color-mixing illumination and display systems and minimizes complexity of driver electronics for said systems. The LED device of one or more embodiments permits compact color-mixing illumination systems that incorporate fewer LEDs. The LED device of one or more embodiments allows one epitaxy manufacturing process (with the same color target) to service both high-power and low-power green LED applications.

### EMBODIMENTS

Various embodiments are listed below. It will be understood that the embodiments listed below may be combined with all aspects and other embodiments in accordance with the scope of the invention.

Embodiment (a). A light emitting diode (LED) device comprising: a quantum well, the device having a dominant wavelength greater than 520 nm, the dominant wavelength changing less than 7 nm when a current density increases from 10 A/cm² to 100 A/cm² and a junction temperature of the device changes less than 20° C.

Embodiment (b). The LED device of embodiment (a), wherein the dominant wavelength changes less than 3 nm as the current density increases from 35 A/cm² to 100 A/cm².

Embodiment (c). The LED device of embodiments (a) to (b), wherein the device has an external quantum efficiency (EQE) greater than 20% when operated at 35 A/cm² at room temperature.

Embodiment (d). The LED device of embodiments (a) to (c), further comprising a superlattice structure on an n-type layer on a nucleation layer on a substrate, the superlattice structure comprising alternating pairs of an indium gallium nitride (InGaN) layer and a gallium nitride (GaN) layer, the quantum well on the superlattice structure.

Embodiment (e). The LED device of embodiments (a) to (d), wherein the quantum well comprises an indium gallium nitride (InGaN) well and a gallium nitride (GaN) barrier layer.

Embodiment (f). The LED device of embodiments (a) to (e), wherein the indium gallium nitride (InGaN) well has an indium concentration greater than 14% mole fraction.

Embodiment (g). The LED device of embodiments (a) to (f), wherein the quantum well comprises an active region doped with silicon.

Embodiment (h). The LED device of embodiments (a) to (g), wherein silicon has a concentration in a range of from 1×10¹⁷ cm⁻³ to 5×10¹⁷ cm⁻³.

Embodiment (i). The LED device of embodiments (a) to (h), further comprising a plurality of p-type layers on the quantum well.

Embodiment (j). The LED device of embodiments (a) to (i), wherein the plurality of p-type layers comprise one or more of an aluminum gallium nitride (AlGaN) layer and a gallium nitride layer (GaN).

Embodiment (k). The LED device of embodiments (a) to (j), wherein the plurality of p-type layers are doped with magnesium (Mg).

Embodiment (l). The LED device of embodiments (a) to (k), wherein the plurality of p-type layers comprise a first magnesium doped p-type aluminum gallium nitride layer, a magnesium doped p-type gallium nitride layer, and a second magnesium doped p-type aluminum gallium nitride layer.

Embodiment (m). The LED device of embodiments (a) to (l), further comprising a p-type contact layer on the plurality of p-type layers.

Embodiment (n). A light emitting diode (LED) device comprising: a nucleation layer on a substrate; an n-type layer on the nucleation layer; a quantum well on the n-type layer, the quantum well comprising an indium gallium nitride (InGaN) well and a gallium nitride (GaN) barrier layer; a plurality of p-type layers on the quantum well; and a p-type contact layer on the plurality of p-type layers, the device having a dominant wavelength greater than 520 nm, the dominant wavelength changing less than 7 nm when a current density increases from 10 A/cm² to 100 A/cm² a junction temperature of the device changes less than 20° C.

Embodiment (o). The LED device of embodiment (n), wherein the device has an external quantum efficiency (EQE) greater than 20% when operated at 35 A/cm² at room temperature.

Embodiment (p). The LED device of embodiments (n) to (o), wherein the indium gallium nitride (InGaN) well has an indium concentration greater than 14% mole fraction.

Embodiment (q). The LED device of embodiments (n) to (p), wherein the quantum well further comprises an active region doped with silicon.

Embodiment (r). The LED device of embodiments (n) to (q), wherein the plurality of p-type layers comprise one or more of an aluminum gallium nitride (AlGaN) layer and a gallium nitride layer (GaN).

Embodiment (s). The LED device of embodiments (n) to (r), wherein the plurality of p-type layers are doped with magnesium (Mg).

Embodiment (t). The LED device of embodiments (n) to (s), further comprising a superlattice structure between the n-type layer and the quantum well, the superlattice structure comprising alternating pairs of an indium gallium nitride (InGaN) layer and a gallium nitride (GaN) layer.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to the terms first, second, third, etc. may be used herein to describe various elements, and these elements should not be limited by these terms. These terms may be used to distinguish one element from another.

Reference throughout this specification to a layer, region, or substrate as being “on” or extending “onto” another element, means that it may be directly on or extend directly onto the other element or intervening elements may also be present. When an element is referred to as being “directly on” or extending “directly onto” another element, there may be no intervening elements present. Furthermore, when an element is referred to as being “connected” or “coupled” to another element, it may be directly connected or coupled to the other element and/or connected or coupled to the other element via one or more intervening elements. When an element is referred to as being “directly connected” or “directly coupled” to another element, there are no intervening elements present between the element and the other element. It will be understood that these terms are intended to encompass different orientations of the element in addition to any orientation depicted in the figures.

Relative terms such as “below,” “above,” “upper,”, “lower,” “horizontal” or “vertical” may be used herein to describe a relationship of one element, layer, or region to another element, layer, or region as illustrated in the figures. It will be understood that these terms are intended to encompass different orientations of the device in addition to the orientation depicted in the figures.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. In one or more embodiments, the particular features, structures, materials, or characteristics are combined in any suitable manner.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. A light emitting diode (LED) device comprising:
a quantum well, the device having a dominant wavelength greater than 520 nm, the dominant wavelength changing less than 7 nm when a current density increases from 10 A/cm² to 100 A/cm² and a junction temperature of the device changes less than 20° C.

2. The LED device of claim 1, wherein the dominant wavelength changes less than 3 nm as the current density increases from 35 A/cm² to 100 A/cm².

3. The LED device of claim 1, wherein the device has an external quantum efficiency (EQE) greater than 20% when operated at 35 A/cm² at room temperature.

4. The LED device of claim 1, further comprising a superlattice structure on an n-type layer on a nucleation layer on a substrate, the superlattice structure comprising alternating pairs of an indium gallium nitride (InGaN) layer and a gallium nitride (GaN) layer, the quantum well on the superlattice structure.

5. The LED device of claim 1, wherein the quantum well comprises an indium gallium nitride (InGaN) well and a gallium nitride (GaN) barrier layer.

6. The LED device of claim 5, wherein the indium gallium nitride (InGaN) well has an indium concentration greater than 14% mole fraction.

7. The LED device of claim 1, wherein the quantum well comprises an active region doped with silicon.

8. The LED device of claim 7, wherein silicon has a concentration in a range of from 1×10¹⁷ cm⁻³ to 5×10¹⁷ cm⁻³.

9. The LED device of claim 1, further comprising a plurality of p-type layers on the quantum well.

10. The LED device of claim 9, wherein the plurality of p-type layers comprise one or more of an aluminum gallium nitride (AlGaN) layer and a gallium nitride layer (GaN).

11. The LED device of claim 10, wherein the plurality of p-type layers are doped with magnesium (Mg).

12. The LED device of claim 10, wherein the plurality of p-type layers comprise a first magnesium doped p-type aluminum gallium nitride layer, a magnesium doped p-type gallium nitride layer, and a second magnesium doped p-type aluminum gallium nitride layer.

13. The LED device of claim 9, further comprising a p-type contact layer on the plurality of p-type layers.

14. A light emitting diode (LED) device comprising:
a nucleation layer on a substrate;
an n-type layer on the nucleation layer;
a quantum well on the n-type layer, the quantum well comprising an indium gallium nitride (InGaN) well and a gallium nitride (GaN) barrier layer;
a plurality of p-type layers on the quantum well; and
a p-type contact layer on the plurality of p-type layers,
the device having a dominant wavelength greater than 520 nm, the dominant wavelength changing less than 7 nm when a current density increases from 10 A/cm² to 100 A/cm² a junction temperature of the device changes less than 20° C.

15. The LED device of claim 14, wherein the device has an external quantum efficiency (EQE) greater than 20% when operated at 35 A/cm² at room temperature.

16. The LED device of claim 14, wherein the indium gallium nitride (InGaN) well has an indium concentration greater than 14% mole fraction.

17. The LED device of claim 14, wherein the quantum well further comprises an active region doped with silicon.

18. The LED device of claim 14, wherein the plurality of p-type layers comprise one or more of an aluminum gallium nitride (AlGaN) layer and a gallium nitride layer (GaN).

19. The LED device of claim 18, wherein the plurality of p-type layers are doped with magnesium (Mg).

20. The LED device of claim 14, further comprising a superlattice structure between the n-type layer and the quantum well, the superlattice structure comprising alternating pairs of an indium gallium nitride (InGaN) layer and a gallium nitride (GaN) layer.
